(19) United States
(12) Patent Application Publication
(10) Pub. No.: US 2014/0055289 A1
(43) Pub. Date: Feb. 27, 2014

(54) THIN ILLUMINATED KEYBOARD

(71) Applicant: Chin-Wen CHOU, New Taipei City (TW)

(72) Inventor: Chin-Wen CHOU, New Taipei City (TW)

(21) Appl. No.: 13/592,134

(22) Filed: Aug. 22, 2012

(51) Int. Cl. H03M 11/00

(52) U.S. Cl. 341/22

(57) ABSTRACT

A thin illuminated keyboard comprises a plurality of keys, a carrying unit and at least one light emission board. The carrying unit includes a baseboard to hold the keys and at least one light guide element located between the keys and baseboard. The light guide element includes at least one light guide port. The baseboard includes at least one installation port that communicates and incorporates with the light guide port to form at least one installation space. The light emission board is located on one side of the baseboard opposite to the keys and has at least one light source held in the installation space to emit light towards the light guide port, and the light is transmitted via the light guide element to project to the corresponding keys for illumination.

### FIELD OF THE INVENTION

The present invention relates to an illuminated keyboard and particularly to a simplified thin illuminated keyboard.

### BACKGROUND OF THE INVENTION

With changes in people's life style these days, people do not use computers only at specific locations or time as in the past but under any environments or conditions. Under a dim or dark environment, due to insufficient light people often cannot make accurate keystrokes to output signals correctly. In order to overcome such a problem, many techniques have been developed on the market, such as in U.S. Pat. Nos. 6,284,988, 6,322,229, 6,199,996, 6,554,442 and 6,987,466. They all use a built-in light emission plate to project light outwards to illuminate the keyboard.

Aside from the aforesaid built-in light emission plate, some keyboards use a light emission strip to generate light. They mainly include an optical mask disposed above a baseboard with an opening formed thereon corresponding to the optical mask and a circuit board located on the baseboard and extended into the opening. The circuit board has a light emission unit in the opening. When the circuit board receives electricity to be powered, the light emission unit generates light which is blocked by the optical mask and projects towards a keycap for illumination. While such technique also can generate illumination, during fabrication the baseboard needs an extra punching process to form the optical mask and opening. Moreover, during assembly the circuit board has to be precisely aligned with the opening and the optical mask. As a result, fabrication process is more complex and assembly cannot be done simply. Furthermore, light emitted from the light emission unit can only project towards the keycap through an aperture formed on the optical mask, and thus the light projection effect is not desirable. Therefore, apart from the aforesaid conventional illuminated keyboards, as many other types of illuminated keyboards have been proposed, if these illuminated keyboards could be well improved, another simplified illuminated keyboard can be developed to provide desirable light projection effect.

### SUMMARY OF THE INVENTION

The primary object of the present invention is to provide an illuminated keyboard with an improved assembly structure to simplify the complexity of conventional techniques.

To achieve the foregoing object, the present invention provides a thin illuminated keyboard which comprises a plurality of keys, a carrying unit and at least one light emission board. The carrying unit includes a baseboard to hold and allow the keys to generate trigger movements, and at least one light guide element located between the keys and baseboard. The light guide element includes at least one light guide port. The baseboard includes at least one installation port communicating and incorporating with the light guide port to form at least one installation space. The light emission board is located on one side of the baseboard opposite to the keys and includes at least one light source held in the installation space. The light source emits light towards the light guide port, and the light is transmitted via the light guide element to project to the corresponding keys.

In one embodiment the light guide element includes a covering portion located on one side of the light guide port facing the keys.

In another embodiment the light guide element is partially located above the baseboard and adjacent to the keys.

In yet another embodiment the light guide element covers the baseboard entirely, and the light guide port is located around the keys.

In yet another embodiment the carrying unit includes at least one optical mask which is located on the light guide element and includes an opaque zone and at least one light permeable zone corresponding to the keys. The optical mask can be partially located above the light emission board or cover the light emission board entirely. The optical mask can also be substituted by an optical mask layer which is coated on the light guide element and includes an opaque zone and at least one light permeable zone corresponding to the keys.

In yet another embodiment the light emission board includes an electronic substrate located on one side of the baseboard opposite to the keys. The light source is a light emission unit located on the electronic substrate and can be a light emitting diode.

In yet another embodiment the carrying unit includes a circuit board which generates corresponding output commands during the trigger movements of the keys. The circuit board includes at least one aperture communicating and incorporating with the installation port and the light guide port to form the installation space. The circuit board can be located between the baseboard and the light guide element or below the baseboard. If the circuit board is located below the baseboard, the light emission board is further located below the circuit board.

In yet another embodiment the carrying unit includes a reflective element located below the circuit board. The reflective element can also be substituted by a reflective layer coated on a lower surface of the circuit board and made of a reflective material.

In yet another embodiment the carrying unit includes a plurality of driven mechanisms located on the baseboard to hold the keys and a plurality of elastic elements each located in one driven mechanism. The elastic element provides a return force to each key to form the trigger movement against the baseboard. The baseboard further includes at least one holding portion to hold the driven mechanism.

In short, the thin illuminated keyboard of the invention mainly provides the installation port and the light guide port respectively on the baseboard and the light guide element corresponding to the keys. The installation port and the light guide port communicate with each other to form the installation space. The light emission board that generates light is located on one side of the baseboard opposite to the keys, and the light source is held in the installation space. Thus light generated by the light source projects to the corresponding keys through the light guide element to generate illumination thereon. Therefore, the thin illuminated keyboard of the invention thus formed can meet the requirement of simpler assembly.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of a first embodiment of the thin illuminated keyboard of the invention.

FIG. 2 is a cross section of the first embodiment of the invention.

FIG. 3 is a schematic view showing light projection according to the first embodiment of the invention.

FIG. 4 is a cross section of a second embodiment of the thin illuminated keyboard of the invention.

FIG. 5 is a cross section of a third embodiment of the thin illuminated keyboard of the invention.

FIG. 6 is an exploded view of a fourth embodiment of the thin illuminated keyboard of the invention.

### DETAILED DESCRIPTION OF THE PREFERRED EMBODIMENTS

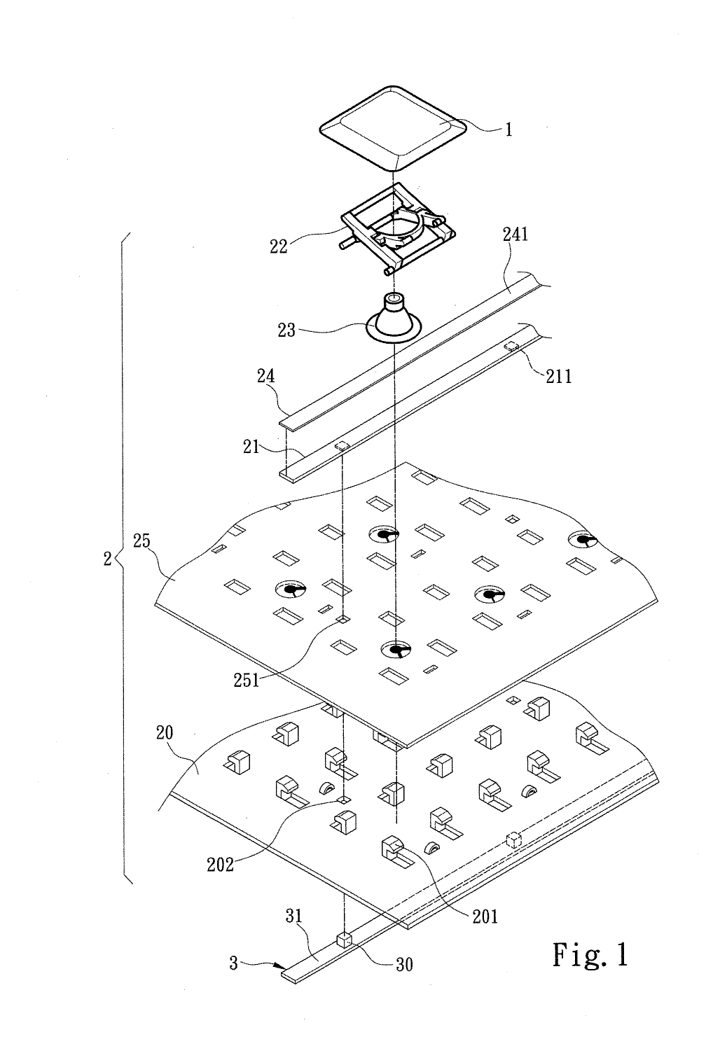

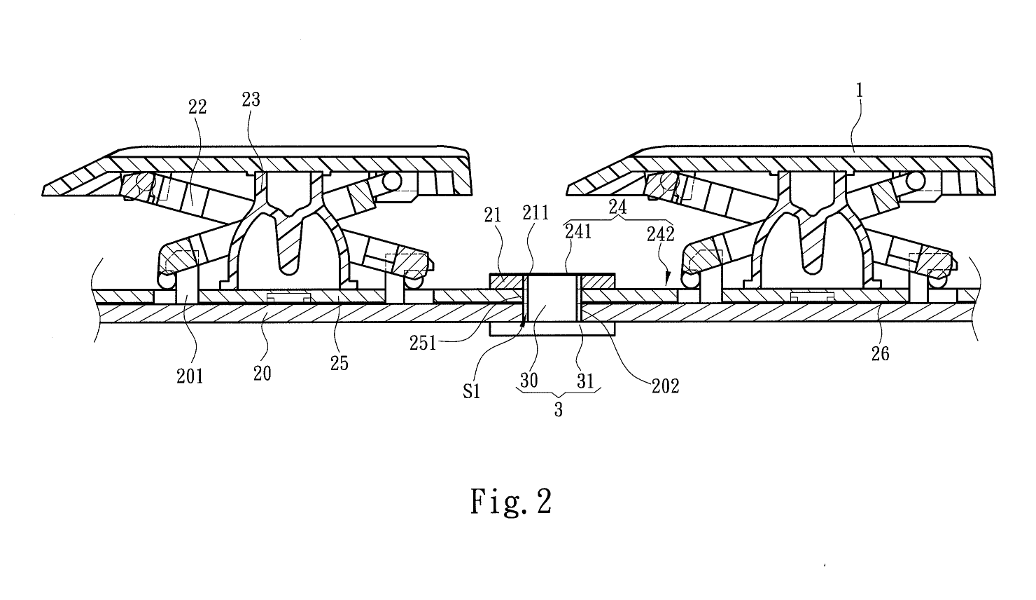

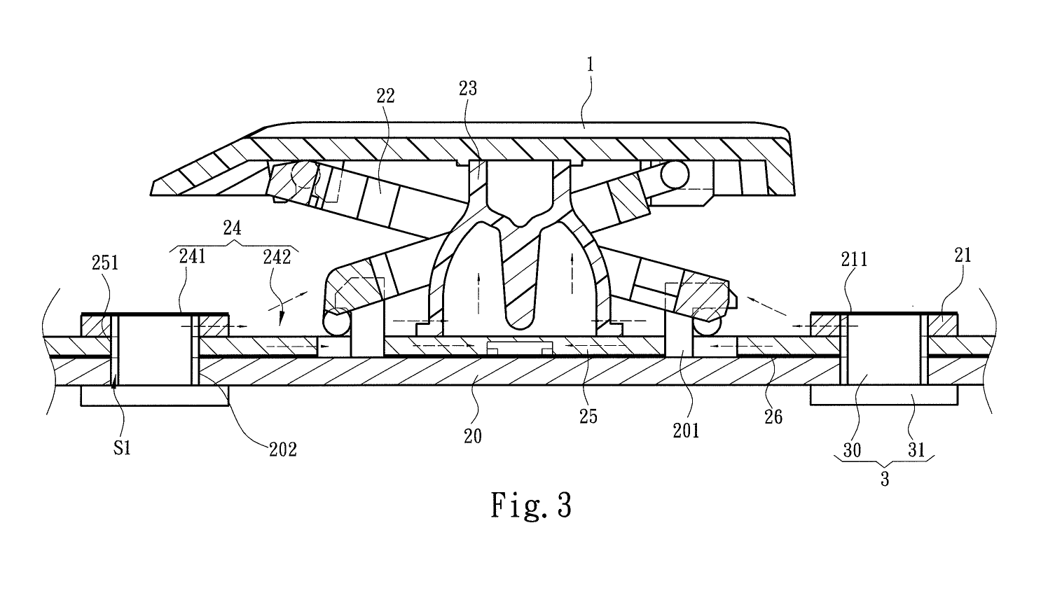

Please refer to FIGS. 1 and 2 for an exploded view and a cross section of the first embodiment of the thin illuminated keyboard of the invention. The thin illuminated keyboard of the invention includes a plurality of keys 1 and a carrying unit 2 to hold the keys 1. The carrying unit 2 includes a baseboard 20 to hold the keys 1 and at least one light guide element 21 located between the keys 1 and baseboard 20. The baseboard 20 includes a plurality of driven mechanisms 22 to hold the keys 1 and a plurality of elastic elements 23 each located in one driven mechanism 22. The elastic elements 23 provide return forces to the keys 1 to form trigger movements against the baseboard 20. More specifically, in the event that the key 1 receives a force and moves towards the baseboard 20, the driven mechanism 22 and the elastic element 23 are also deformed. When the force is absent, the elastic element 23 is free from the compression of the key 1 and returns to its regular condition to provide the return force for the key 1 so that the key 1 returns to the original condition as well. The baseboard 20 further includes at least one holding portion 201 to hold the driven mechanism 22. The light guide element 21 can be a light guide plate or an object capable of guiding light. Furthermore, the light guide element 21 is located adjacent to the keys 1 and has at least one light guide port 211. The baseboard 20 has at least one installation port 202 corresponding to the light guide port 211. The light guide port 211 communicates and incorporates with the installation port 202 to form an installation space S1. A light emission board 3 is further provided on one side of the baseboard 20 opposite to the keys 1 that can generate light when being powered. The light emission board 3 includes at least one light source 30 held in the installation space S1. More specifically, during assembly, the light emission board 3 is mounted on one side of the baseboard 20 in the direction towards the keys 1, so that the light source 30 is held in the installation space S1. The light emission board 3 can include an electronic substrate 31 on one side of the baseboard 20 opposite to the keys 1 to hold the light source 30. The light source 30 can be a light emission unit laid on the electronic substrate 31, such as a light emitting diode (LED) or the like. Please also refer to FIG. 3 for a schematic view showing light projection according to the first embodiment of the invention. When the light emission board 3 is powered, the light source 30 (i.e. light emission unit) generates light which projects towards the light guide port 211 and is transmitted via the light guide element 21 to the corresponding keys 1 to generate illumination thereon.

Also referring back to FIGS. 1 and 2, the carrying unit 2 further includes at least one optical mask 24 on the light guide element 21. The optical mask 24 includes an opaque zone 241 and at least one light permeable zone 242 corresponding to the keys 1. When the light guide element 21 receives the light projected from the light emission board 3, because of the light shielding effect of the optical mask 24, the light can only pass through the light permeable zone 242 to illuminate the keys 1 which correspond to the light permeable zone 242. While this embodiment takes the optical mask 24 as an example, in practice the optical mask 24 can be substituted by an optical mask layer coated on the light guide element 21 with the light permeable zone and opaque zone formed thereon. The optical mask layer is functioned same as the optical mask 24, hence details are omitted.

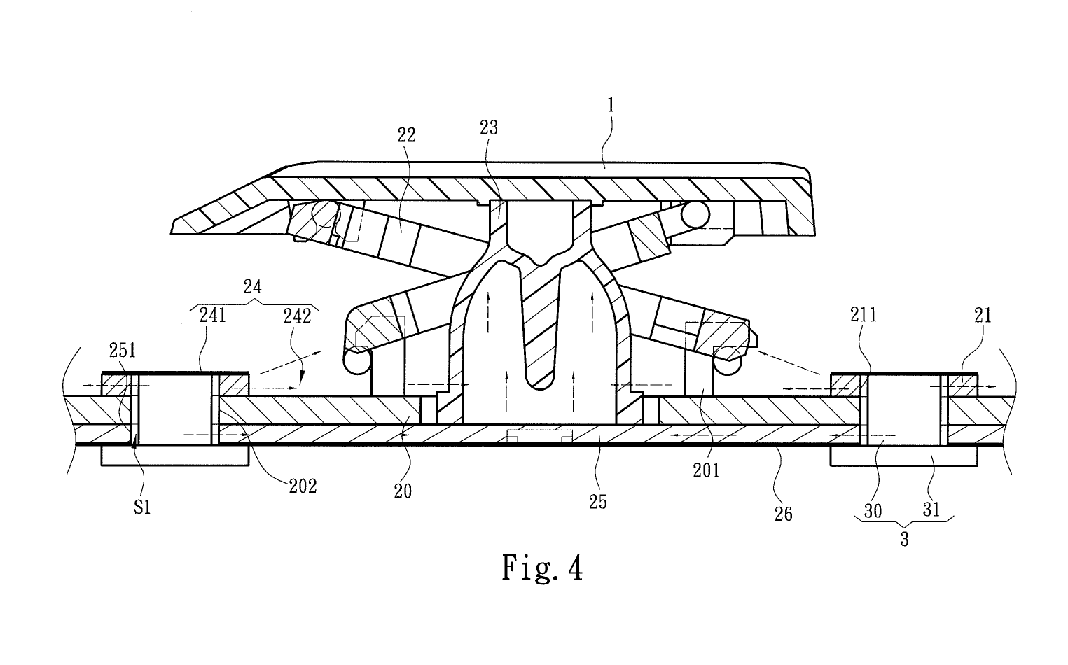

At present, there are two types of keyboard structure commonly adopted in the industry. One is depicted in FIGS. 1 and 2 of the invention, in which the carrying unit 2 includes a circuit board 25 located between the baseboard 20 and the light guide element 21. The circuit board 25 generates corresponding output commands during the trigger movements of the keys 1 upon receiving a force. The circuit board 25 further includes at least one aperture 251 communicating and incorporating with the installation port 202 and the light guide port 211 to form the installation space S1. The other type of keyboard structure is shown in a second embodiment of the invention in FIG. 4. The circuit board 25 is located below the baseboard 20, and the aperture 251 also communicates and incorporates with the installation port 202 and the light guide port 211 to form the installation space S1. In this embodiment, the electronic substrate 31 of the light emission board 3 is further located below the circuit board 25. Both the previously discussed embodiments are well-known techniques, hence details are omitted.

Please refer to FIGS. 3 and 4, at present many types of embodiments of the circuit board 25 of the keyboard are available. In the event that the circuit board 25 is made of light permeable material, the light generated by the light emission board 3 projects randomly through the circuit board 25. Therefore, the invention provides a reflective element 26 below the circuit board 25 of the carrying unit 2. When the light emission board 3 projects light towards the light guide element 21, a portion of the light penetrates into the light permeable circuit board 25 and is directly reflected by the reflective element 26 to project towards the keys 1. In addition, the reflective element 26 provides not only light reflection effect but also light shielding effect. The light shielding effect of the reflective element 26 means that light can be blocked and does not project towards the baseboard 20 or other elements. Moreover, the reflective element 26 can also be substituted by a reflective layer which is coated on a lower surface of the circuit board 20 and made of a reflective material.

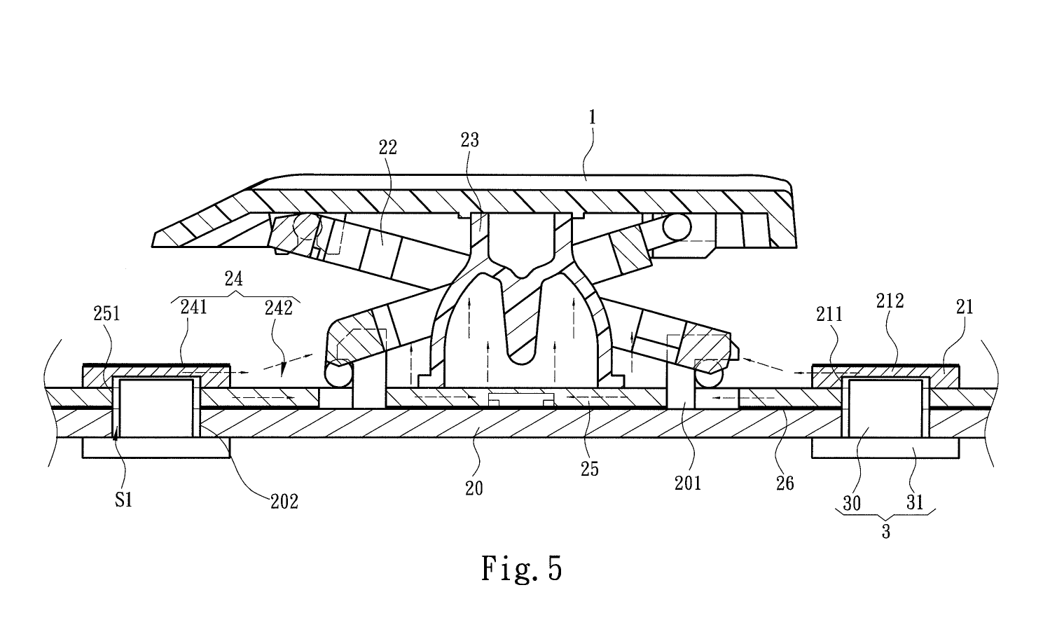

Please refer back to FIG. 2, in the first embodiment, the light guide port 211 penetrates through the light guide element 21, but it is not the limitation. Please refer to FIG. 5 for a third embodiment of the invention. The light guide element 21 includes a covering portion 212 on one side of the light guide port 211 facing the keys 1. When the light guide port 211 is covered by the covering portion 212, the light source 30 of the light emission board 3 is embedded in the light guide port 211 with one end covered by the covering portion 212. Light enters into the light guide element 21 via the light guide port 211 and covering portion 212 to project towards the keys 1.

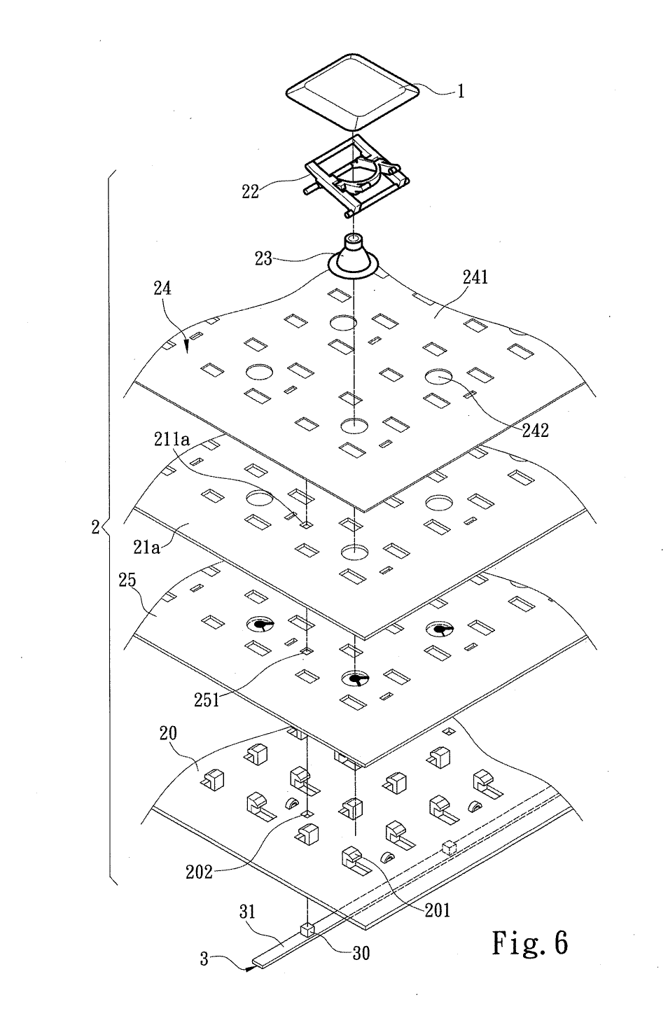

Please refer to FIG. 6 for an exploded view of a fourth embodiment of the invention. While the aforesaid embodiments provide the light guide element 21 partially located above the baseboard 20, in the fourth embodiment, a light guide element 21a is also located above the baseboard 20 but it covers the baseboard 20 entirely rather than partially. The light guide element 21a also includes a light guide port 211a which can also be covered by a covering portion (not shown in the drawing) as the third embodiment does. Furthermore, the light guide port 211a can be located around the keys 1 without being projected by the light from the keys 1. The installation port 202 also communicates and incorporates with the corresponding light guide port 211a to form the installation space S1. Also referring to FIG. 1, the optical mask 24 is partially located above the light emission board 3 to form the opaque zone 241 and the light permeable zone 242, but it is not the limitation as the optical mask 24 can also cover the entire light emission board 3.

As a conclusion, the thin illuminated keyboard of the invention provides the installation port and light guide port respectively on the baseboard and light guide element corresponding to the keys. The installation port and the light guide port communicate and incorporate with each other to form the installation space to hold the light source of the light emission board. Thus light generated by the light source projects to the corresponding keys via the light guide element.

Therefore, the invention provides an illuminated keyboard with a simpler structure than conventional illuminated keyboards, and also can be assembled in simplified fabrication processes.

While the preferred embodiments of the invention have been set forth for the purpose of disclosure, they are not the limitations of the invention, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A thin illuminated keyboard, comprising:
a plurality of keys;
a carrying unit including a baseboard to hold and allow the plurality of keys to generate trigger movements and at least one light guide element located between the plurality of keys and the baseboard, the at least one light guide element including at least one light guide port, the baseboard including at least one installation port communicating and incorporating with the at least one light guide port to form at least one installation space; and
at least one light emission board which is located on one side of the baseboard opposite to the plurality of keys and includes at least one light source held in the at least one installation space to generate light emitted towards the at least one light guide port and transmitted via the at least one light guide element to project to the corresponding keys.

2. The thin illuminated keyboard of claim 1, wherein the at least one light guide element includes a covering portion on one side of the at least one light guide port facing the plurality of keys.

3. The thin illuminated keyboard of claim 1, wherein the carrying unit includes at least one optical mask which is located on the at least one light guide element and includes an opaque zone and at least one light permeable zone corresponding to the plurality of keys.

4. The thin illuminated keyboard of claim 3, wherein the at least one optical mask is partially located above the at least one light emission board.

5. The thin illuminated keyboard of claim 3, wherein the at least one optical mask covers the at least one light emission board entirely.

6. The thin illuminated keyboard of claim 1, wherein the at least one light guide element is partially located above the baseboard and adjacent to the plurality of keys.

7. The thin illuminated keyboard of claim 1, wherein the at least one light guide element covers the baseboard entirely.

8. The thin illuminated keyboard of claim 1, wherein the at least one light guide port is located around the plurality of keys.

9. The thin illuminated keyboard of claim 1, wherein the carrying unit includes at least one optical mask layer which is coated on the at least one light guide element and includes an opaque zone and at least one light permeable zone corresponding to the plurality of keys.

10. The thin illuminated keyboard of claim 1, wherein the at least one light emission board includes an electronic substrate on one side of the baseboard opposite to the plurality of keys, the at least one light source being a light emission unit located on the electronic substrate.

11. The thin illuminated keyboard of claim 10, wherein the light emission unit is a light emitting diode.

12. The thin illuminated keyboard of claim 1, wherein the carrying unit includes a circuit board which generates output commands during the trigger movements of the plurality of keys.

13. The thin illuminated keyboard of claim 12, wherein the circuit board includes at least one aperture communicating and incorporating with the at least one installation port and the at least one light guide port to form the at least one installation space.

14. The thin illuminated keyboard of claim 12, wherein the circuit board is located between the baseboard and the at least one light guide element.

15. The thin illuminated keyboard of claim 12, wherein the circuit board is located below the baseboard.

16. The thin illuminated keyboard of claim 15, wherein the at least one light emission board is located below the circuit board, the at least one light source being held in the at least one installation space.

17. The thin illuminated keyboard of claim 12, wherein the carrying unit includes a reflective element located below the circuit board.

18. The thin illuminated keyboard of claim 12, wherein the carrying unit includes a reflective layer coated on a lower surface of the circuit board and made of a reflective material.

19. The thin illuminated keyboard of claim 1, wherein the carrying unit includes a plurality of driven mechanisms on the baseboard to hold the plurality of keys and a plurality of elastic elements each located in one of the plurality of driven mechanisms, the plurality of elastic elements providing return forces to the plurality of keys to form the trigger movements against the baseboard.

20. The thin illuminated keyboard of claim 19, wherein the baseboard includes at least one holding portion to hold one of the plurality of driven mechanisms.
